(19) United States
(12) Patent Application Publication
(10) Pub. No.: US 2026/0282659 A1
(43) Pub. Date: Sep. 17, 2026

(54) DISPLAY PANEL, METHOD OF MANUFACTURING DISPLAY PANEL, AND DISPLAY APPARATUS

(71) Applicant: HKC CORPORATION LIMITED, SHENZHEN (CN)

(72) Inventors: Shengxun SU, SHENZHEN (CN); Xiufeng ZHOU, SHENZHEN (CN); Zhisheng XIE, SHENZHEN (CN); Yangling TANG, SHENZHEN (CN); Qin LIANG, SHENZHEN (CN); Zhi YANG, SHENZHEN (CN); Haijiang YUAN, SHENZHEN (CN)

(21) Appl. No.: 19/556,967

(22) Filed: Mar. 4, 2026

(30) Foreign Application Priority Data
Mar. 12, 2025 (CN) 202510290593.8

(51) Int. Cl. H10K 59/122; H10K 50/19; H10K 59/12; H10K 59/32; H10K 59/80

(52) U.S. Cl. CPC H10K 59/122; H10K 50/19; H10K 59/1201; H10K 59/32; H10K 59/8723

(57) ABSTRACT

A display panel, includes: a driver substrate; a pixel definition layer, protrudingly from the driver substrate and defining pixel openings; and sub-pixel, each having an anode electrode, at least two light emitting function layers, and a cathode electrode. A charge generation layer is disposed between adjacent two light emitting function layers and includes a first charge generation layer, a metal connection layer, and a second charge generation layer. The cathode electrode extends out of one pixel opening and is electrically connected to the cathode electrode of another pixel opening. A first isolation layer is arranged on the pixel definition layer; the first isolation layer forms a mesh to enclose the pixel openings. The first isolation layer and a metal material repel from each other, the metal connection layer in one pixel opening is disconnected from the metal connection layer of another pixel opening.

### CROSS REFERENCE TO RELATED APPLICATIONS

The present application claims the priority of the Chinese patent application No. 202510290593.8, filed on Mar. 12, 2025, contents of which are incorporated herein by its entireties.

### TECHNICAL FIELD

Embodiments of the present disclosure relate to the technical field of displaying, and more specifically, to a display panel, a method of manufacturing the display panel, and a display apparatus.

### BACKGROUND

As demands of end-users continuously improve, requirements for the display technology are increasing, and in order to meet growing demands of the users, various new technologies have emerged, such as color filter on encapsulation (COE), integration of a micro lens array (MLA), the eLEAP maskless technology, the transparent display technology, the stacking technology, and so on. For the stacking technology, high brightness, a long service life, and other advantages may be achieved, and therefore, the stacking technology may be determined as the new technology that needs to be developed by various panel manufacturers and terminal manufacturers.

However, disadvantages of the stacking technology may also be obvious. Firstly, structures of a stacking device may be more complicated than structures of a single-layer device, and therefore, costs for materials and equipment investment may be substantially increased. Secondly, compared to the single-layer device, a product yield of the stacking device may be lower, especially a cathode and a charge generation layer (CGL) may be tandem conducted to each other. In addition, in order to further reduce a voltage of the stacking device and improve stability thereof, a metal layer of good conductivity may be additionally arranged in a structural layer of the CGL. However, a distance between the metal layer in the CGL and the cathode may be extremely small, and when vaporizing a light emitting functional layer at an upper layer of the stacking device, a high-precision metal fine mask plate (FMM)) may repeatedly rub a pixel definition layer (PDL) and a photo spacer (PS), such that the metal layer in the CGL layer may be exposed to be conducted with the cathode.

### SUMMARY

The present disclosure provides a display panel, a method of manufacturing the display panel, and a display apparatus, so as to solve the technical problem that the CGL and the cathode in the stacking OLED may be easily tandem conducted with each other.

In a first aspect, the present disclosure a display panel, including:

a driver substrate;

a pixel definition layer, protrudingly arranged on the driver substrate and defining a plurality of pixel openings;

a plurality of sub-pixel, each of the plurality of sub-pixel including an anode electrode, at least two stacked light emitting function layers, and a cathode electrode, where the anode electrode, the at least two stacked light emitting function layers, and the cathode electrode are stacked in a respective one of the plurality of pixel openings; a charge generation layer is disposed between adjacent two of the at least two light emitting function layers; the charge generation layer includes a first charge generation layer, a metal connection layer, and a second charge generation layer that are sequentially stacked; the cathode electrode extends out of one respective pixel opening and is electrically connected to the cathode electrode of another pixel opening adjacent to the one respective pixel opening.

A first isolation layer is arranged on a side surface of the pixel definition layer away from the driver substrate; the first isolation layer extends along an extension direction of the pixel definition layer to form a mesh to enclose the plurality of pixel openings; the first isolation layer and a metal material repel from each other, so as to isolate the metal connection layer of one respective pixel opening from the metal connection layer of another pixel opening adjacent to the one respective pixel opening.

In a second aspect, the present disclosure provides a method of manufacturing a display panel, including:

providing a pre-prepared plate; where the pre-prepared plate includes a driver substrate, a pixel definition layer, and a plurality of anode electrodes; the pixel definition layer is protrudingly arranged on the driver substrate and defines a plurality of pixel openings; each of the plurality of anode electrodes is received in a respective one of the plurality of pixel openings;

depositing and forming a first light emitting function layer and a first charge generation layer sequentially in each of the plurality of pixel openings;

depositing and forming a first isolation layer on the pixel definition layer; where the first isolation layer extends in an extension direction of the pixel definition layer to form a mesh to enclose the plurality of pixel openings; the first isolation layer and a metal material repel from each other;

depositing and forming a metal connection layer in each of the plurality of pixel openings; where the metal connection layer in one of the plurality of pixel openings is disconnected from the metal connection layer in another one of the plurality of pixel openings at positions where the first isolation layer is arranged;

depositing and forming a second charge generation layer, a second light emitting functional layer, and a cathode electrode in each of the plurality of pixel openings; where the cathode electrode extends out of a respective one of the plurality of pixel openings to be electrically connected to the cathode electrode the cathode electrode of another one of the plurality of pixel openings adjacent to the respective one of the plurality of pixel openings.

In a third aspect, the present disclosure provides a display apparatus, including:

the display panel in the above embodiments; and

a control circuit board, electrically connected to the display panel and configured to control the display panel to display a corresponding image.

### BRIEF DESCRIPTION OF THE DRAWINGS

In order to more clearly illustrate technical solutions in embodiments of the present disclosure, accompanying drawings used for describing the embodiments will be briefly introduced below. Apparently, the accompanying drawings in the following description are only some of the embodiments of the present disclosure, and any ordinary skilled person in the art may obtain other accompanying drawings based on these drawings without making any creative work.

FIG. 1 is a cross-sectional view of a display panel according to a first embodiment of the present disclosure.

FIG. 2 is a plane view of the display panel according to the first embodiment of the present disclosure.

FIG. 3 is another cross-sectional view of the display panel according to the first embodiment of the present disclosure.

FIG. 4 is a cross-sectional view of the display panel according to a second embodiment of the present disclosure.

FIG. 5 is a plane view of the display panel according to the second embodiment of the present disclosure.

FIG. 6 is another cross-sectional view of the display panel according to the second embodiment of the present disclosure.

FIG. 7 is a vertical cross-sectional view of the display panel according to a third embodiment of the present disclosure.

FIG. 8 is another vertical cross-sectional view of the display panel according to the third embodiment of the present disclosure.

FIG. 9 is a flow chart of a method of manufacturing the display panel according to a first implementation of the present disclosure.

FIG. 10 is a structural schematic view of a component corresponding to the method shown in FIG. 9.

FIG. 11 is a flow chart of a method of manufacturing the display panel according to a second implementation of the present disclosure.

FIG. 12 is a structural schematic view of a component corresponding to the method shown in FIG. 11.

FIG. 13 is a flow chart of a method of manufacturing the display panel according to a third implementation of the present disclosure.

FIG. 14 is a structural schematic view of a component corresponding to the method shown in FIG. 13.

FIG. 15 is a structural schematic view of a display apparatus corresponding to an embodiment of the present disclosure.

Reference numerals in the drawings:

100-display panel; 10-driver substrate; 20-pixel definition layer; 21-pixel opening; 22-photo spacer; 30-sub-pixel; 31-anode electrode; 32-light emitting function layer; 321-first light emitting function layer; 322-second light emitting function layer; 33-charge generation layer; 331-first charge generation layer; 332-second charge generation layer; 333-metal connection layer; 34-cathode electrode; 41-first isolation layer; 42-second isolation layer; 200-control circuit board.

### DETAILED DESCRIPTIONS

The technical solutions in the embodiments of the present disclosure will be described in detail below by referring to the accompanying drawings of the present disclosure.

In the following description, specific details such as particular system structures, interfaces, techniques, and the like are described for purposes of illustration and not for purposes of limitation, so as to provide thorough understanding of the present disclosure.

The technical solutions in the embodiments of the present disclosure will be described clearly and comprehensively below by referring to the accompanying drawings of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear ......) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

As the display technology develops, an organic light emitting diode (OLED) display panel has become one of mainstream display technologies in the future due to various advantages, such as self-luminescence, having a wide viewing angle and fast response time, being thin in size and light in weight, and being bendable. The underlying technology of sub-pixels is determined as an essential new technology to be developed by various display panel manufacturers and terminal manufacturers due to advantages of having high brightness and a long service life. In order to further reduce a voltage of the light emitting device and improve stability thereof, a metal layer of good conductivity may be additionally arranged in a structural layer of a charge generation layer (CGL). However, a high-precision fine metal mask (FMM) is to be used for a subsequent evaporation stage for forming a light emitting functional layer after the metal connection layer. The FMM may repeatedly a the pixel definition layer (PDL) and a photo spacer (PS), such that the metal layer in the CGL layer may be exposed, and the distance between the metal connection layer and the cathode electrode may be excessively small. When the light emitting function layer is subsequently formed by the evaporation, due to the distance between the metal connection layer and the cathode electrode being excessively small, and when a current flowing through sub-pixels of the stacking structure is excessively large, the light emitting function layer may be highly likely to be broken through by the current. In this case, the cathode electrode and the metal connection layer in the charge generation layer may be directly tandem conducted to each other, such that the display panel may have a poor touch effect. Moreover, after the metal connection layer is additionally arranged in the CGL, due to transverse conductive crosstalk, when one sub-pixel is lit, the light emitting functional layer above another sub-pixel adjacent to the one sub-pixel may also be lit, such that transverse crosstalk lighting may be caused.

In order to solve the above technical problems, a groove may be defined in the pixel definition layer or an undercut may be formed, such that the metal connection layer in the charge generation layer may be disconnected at the groove or the undercut, and the tandem conduction of the metal connection layer and the cathode electrode and transverse conductive crosstalk may be solved. However, processing for forming the groove and the undercut may be complicated, and continuity of the cathode electrode film layer that is deposited subsequently may be reduced, such that abnormal conductivity of the cathode may be caused.

According to the present disclosure, a display panel, a method of manufacturing the display panel, and a display apparatus are provided. The display panel includes a driver substrate, a pixel definition layer, and sub-pixels. Each sub-pixel is received in a pixel opening and includes an anode electrode, at least two light emitting function layers that are stacked, a cathode electrode, and a charge generation layer disposed between adjacent two of the at least two light emitting function layers, such that a light emitting device having a stacking structure is formed, such that brightness and a service life of the display panel may be improved. The charge generation layer includes a first charge generation layer, a metal connection layer, and a second charge generation layer that are stacked sequentially, and that is, the metal connection layer is disposed between the first charge generation layer and the second charge generation layer. In this way, a voltage of the sub-pixels of the stacking structure is reduced, and stability of a current of the sub-pixels may be improved. Further, a first isolation layer may be arranged on a side surface of the pixel definition layer away from the driver substrate, such that the first isolation layer extends along an extension direction of the pixel definition layer to form a mesh to enclose pixel openings. The first isolation layer and the metal material may repel each other, such that the metal connection layer may be unable to be deposited on the first isolation layer, such that adjacent metal connection layers may be isolated from each other, such that the metal connection layer may be confined within the pixel opening, and transverse conductive crosstalk between metal connection layers may be reduced, and therefore, transverse crosstalk between sub-pixels may be reduced. Furthermore, in a subsequent process of evaporation for forming the light emitting functional layers, when the FMM frequently rubs the pixel definition layer and the photo spacer during alignment, the above configuration may reduce exposure of the metal connection layers due to rubbing, and the distance between the metal connection layer and the cathode electrode may be prevented from being reduced. In this way, direct conduction between the metal connection layer and the cathode electrode, caused by a large current breaking through the light emitting function layer due to the small distance between the metal connection layer and the cathode electrode, may be reduced, and poor screen touch and transverse crosstalk of sub-pixels caused by the tandem conduction between the metal connection layer and the cathode electrode may be reduced.

The present disclosure will be described in detail by referring to the accompanying drawings and embodiments.

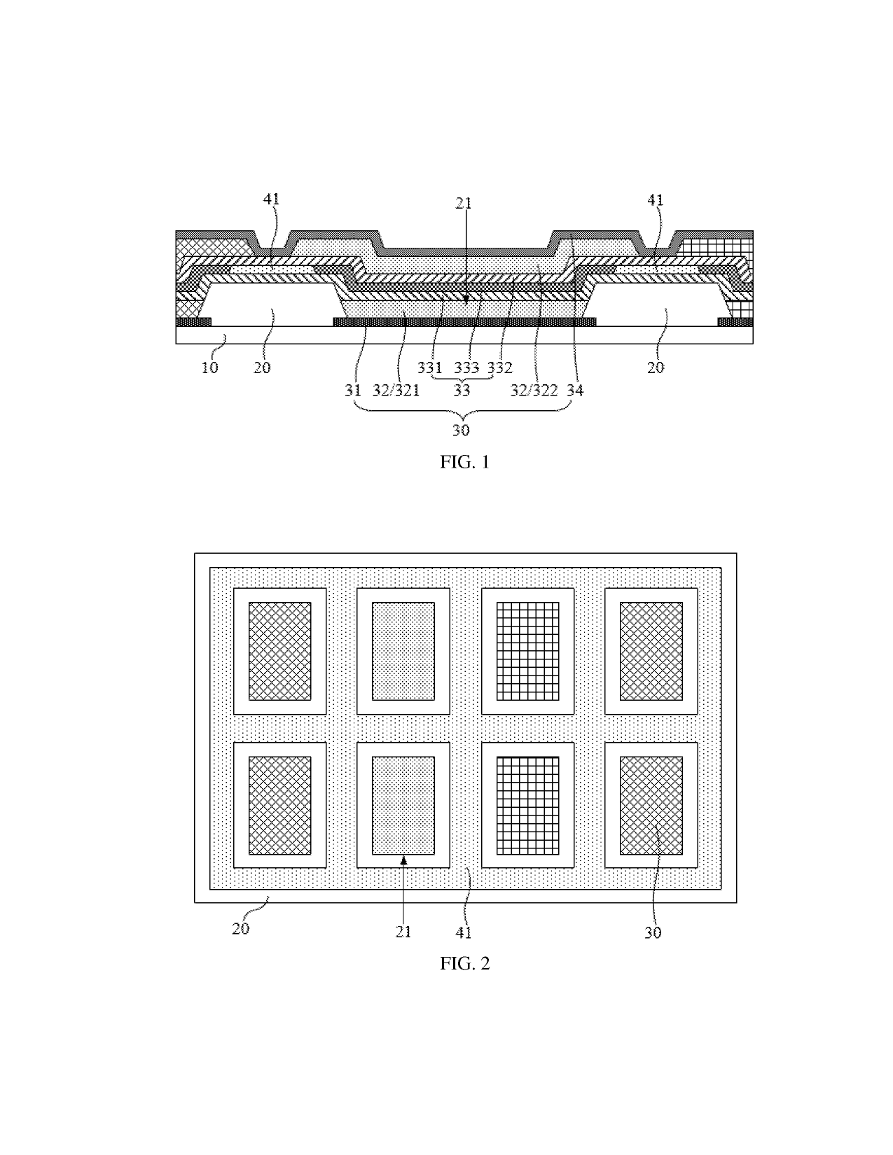

As shown in FIGS. 1 and 2, FIG. 1 is a cross-sectional view of a display panel according to a first embodiment of the present disclosure; and FIG. 2 is a plane view of the display panel according to the first embodiment of the present disclosure. In the present embodiment, a display panel 100 is provided, the display panel 100 includes the following.

A driver substrate 10 is arranged.

A pixel definition layer 20 may be protrudingly disposed on the driver substrate 10 and may have a plurality of pixel openings 21.

A plurality of sub-pixels 30 may be arranged, and each of plurality of sub-pixels 30 may include an anode electrode 31, at least two light emitting function layers 32 that are stacked, and a cathode electrode 34. The anode electrode 31, the at least two light emitting function layers 32, and the cathode electrode 34 of each sub-pixel 30 may be stacked and received in a respective one of the plurality of pixel openings 21. A charge generation layer 33 may be disposed between adjacent two of the at least two light emitting function layers 32. The charge generation layer 33 may include a first charge generation layer 331, a metal connection layer 333, and a second charge generation layer 332 that are sequentially stacked. The cathode electrode 34 of one sub-pixel may extend out of each of the plurality of pixel openings 21 and may be electrically connected to the cathode electrode 34 of another sub-pixel adjacent to the one sub-pixel.

A first isolation layer 41 may be arranged on a side surface of the pixel definition layer 20 away from the driver substrate 10. The first isolation layer 41 extends along an extension direction of the pixel definition layer 20 to form a mesh to enclose the plurality of pixel openings 21. The first isolation layer 41 and a metal material may repel each other, so as to isolate the metal connection layer 333 in one sub-pixel from the metal connection layer 333 in another sub-pixel adjacent to the one sub-pixel.

The driver substrate 10 may include a drive circuit configured to drive the plurality of sub-pixels 30 to emit light. The driver substrate 10 may be a silicon-based driver substrate 10, such as a monocrystalline silicon driver substrate 10 or a polycrystalline silicon driver substrate 10. The driver substrate 10 may be a rigid substrate or a flexible driver substrate 10. A structure of the driver substrate 10 may be determined according to application scenarios and usage requirements. The drive circuit may include a plurality of sub-pixel drive circuits. Each of the plurality of sub-pixel drive circuits may include at least one semiconductor driver member and at least one energy storage member and may be configured to provide drive signals to each sub-pixel 30, so as to drive the sub-pixel 30 to emit light.

The pixel definition layer 20 may be arranged on the driver substrate 10 and protrude out from the driver substrate 10 to form the plurality of pixel openings 21 for receiving the plurality of sub-pixels 30 respectively. Specifically, the plurality of pixel openings 21 may be formed by patterning and etching. For example, a photolithography process or some other patterning processes may be performed, the plurality of pixel openings 21 may be formed by etching. The plurality of pixel openings 21 may be arranged in an array, and arrangement of the plurality of pixel openings 21 may be determined according to arrangement of the plurality of sub-pixels 30.

Each of the plurality of sub-pixels 30 may be received in the respective one pixel opening 21 and electrically connected to the driver substrate 10 so as to receive the drive signal to correspondingly display images. Specifically, each sub-pixel 30 may include the anode electrode 31, the at least two stacked light emitting function layers 32, and the cathode electrode 34 that are sequentially stacked along a direction away from the driver substrate 10 to form a series-type stacking light emitting device. In this way, display brightness may be improved, and a service life may be extended.

Specifically, the anode electrode 31 may be arranged on the driver substrate 10 and electrically connected to a respective one of the plurality of sub-pixel drive circuits, such that the anode electrode 31 may serve as an anode of the sub-pixel 30 to receive the drive signal. The anode electrode 31 may be exposed from the pixel opening 21 to be in contact with and connected to one of the at least two light emitting functional layers 32. A material of the anode electrode 31 may include one or combination of a metal and a conductive metal oxide. The metal may be a metal conductive material, such as gold (Au), silver (Ag), copper (Cu), aluminum (Al), and so on. The metal oxide may be a conductive metal oxide material, such as indium-tin oxide (ITO), indium-zinc-oxide (IZO), indium-gallium-zinc-oxide (IGZO), and so on. For example, the anode electrode 31 may be a multilayer structure having “an ITO layer – a metal layer – an ITO layer”. Specific material thereof may be determined according to actual demands. The anode electrode 31 may be formed by being patterned by a patterning process, and the patterning process may be a photolithography process or an evaporation deposition process.

Specifically, the at least two light emitting functional layers 32 may at least include a hole transport layer, a light emitting layer, and an electron transport layer that are stacked sequentially, so as to form a light emitting unit. Further, the functional layer may further include a hole injection layer, an electron blocking layer, and a hole blocking layer. The hole injection layer may be disposed between the anode electrode 31 and the hole transport layer, the electron blocking layer may be disposed between the hole transport layer and the light emitting layer, and the hole blocking layer may be disposed between the light emitting layer and the electron transport layer. Specifically, arrangement of the at least two light emitting functional layers 32 may be determined according to application environments of the display panel 100 and light emitting demands, which will not be limited herein.

It should be noted that, in an embodiment, the sub-pixel 30 may include at least two stacked light emitting function layers 32. Specifically, the sub-pixel 30 may include a first light emitting function layer 321, a second light emitting function layer 322, a third light emitting function layer, or even more. The above-described charge generation layer 33 may be disposed between every adjacent two of the at least two light emitting function layers 32. In the present embodiment, the two stacked light emitting function layers 32, including the first light emitting function layer 321 and the second light emitting function layer 322, will be described as an example. However, it shall not be interpreted as the sub-pixel 30 including only two light emitting function layers 32. In other embodiments, the sub-pixel 30 may include even more stacked light emitting function layers 32. In the present embodiment, the two stacked light emitting function layers 32 may be the first light emitting function layer 321 and the second light emitting function layer 322. The first light emitting function layer 321 may be disposed between the anode electrode 31 and the charge generation layer 33, and the second light emitting function layer 32 may be disposed between the charge generation layers 33 and the cathode electrode 34.

Specifically, a color of light emitted from the first light emitting function layer 321 and a color of light emitted from the second light emitting function layer 322 may be the same, such that a color of the sub-pixel 30 is consistent with the color of the light emitted from the two light emitting function layers 32. Specifically, the plurality of sub-pixels 30 may include a red sub-pixel 30, a green sub-pixel 30, and a blue sub-pixel 30. The red sub-pixel 30, the green sub-pixel 30, and the blue sub-pixel 30 may be distributed and arranged based on a predetermined arrangement rule of colors of sub-pixels 30. The red sub-pixel 30, the green sub-pixel 30, and the blue sub-pixel 30, which are adjacent to each other, may form one pixel unit. In some embodiments, the plurality of sub-pixels 30 may further include a white sub-pixel 30, and the pixel unit may further include the white sub-pixel 30. In some embodiments, in one sub-pixel 30, the color of the light emitted from the first light emitting functional layer 321 may be different from the color of the light emitted from the second light emitting function layer 322. In this way, a sub-pixel 30 of a special color may be formed, satisfying some special display requirements.

The charge generation layer 33 may be disposed between the adjacent two light emitting function layers 32 and may be configured to generate carriers and to transmit the carriers to a corresponding film layer. The charge generation layer 33 may include a first charge generation layer 331, a metal connection layer 333, and a second charge generation layer 332 that are sequentially stacked. Specifically, the first charge generation layer 331 and the second charge generation layer 332 may be an N-type charge generation layer and a P-type charge generation layer, respectively. The N-type charge generation layer may be configured to generate electrons and transmit the electrons to the corresponding film layer, and the P-type charge generation layer may be configured to generate holes and transmit the holes to the corresponding film layer. The first charge generation layer 331 may be the N-type charge generation layer and the second charge generation layer 332 may be the P-type charge generation layer. Alternatively, the first charge generation layer 331 may be the P-type charge generation layer and the second charge generation layer 332 may be the N-type charge generation layer. Specific arrangement of the first charge generation layer 331 and the second charge generation layer 332 may be determined according to the actual demands. The metal connection layer 333 may be configured to reduce a voltage of the stacking light emitting device to improve current stability of the stacking light emitting device. A material of the metal connection layer 333 may be a metal material, which may be a metal conductive material such as gold (Au), silver (Ag), copper (Cu), aluminum (Al), or an alloy material of more than one of the above materials.

The cathode electrode 34 may be arranged on one of the at least two light emitting function layers 32 that is furthest away from the driver substrate 10 and may cover the furthest light emitting function layer 32. Cathode electrodes 34 of the adjacent two of the plurality of sub-pixels 30 may be electrically connected to each other, so as to form one integral surface electrode, such that homogeneity of a cathode signal may be improved. A material of the cathode electrode 34 may be a metal material, such as aluminum (Al), silver (Ag), lithium (Li), magnesium (Mg), calcium (Ca), indium (In), and other metal conductive materials having a lower work function, such that electron injection may be facilitated. Alternatively, the material of the cathode electrode 34 may be a magnesium-silver alloy (Mg:Ag), a lithium-aluminum alloy (Li:Al), and other alloys formed from metals, which have the lower work function and are chemically active, and metals that are chemically stable and have a high work function.

In the present embodiment, the first isolation layer 41 may be arranged on the side surface of the pixel definition layer 20 away from the driver substrate 10. The first isolation layer 41 may extend in the extension direction of the pixel definition layer 20 to form the mesh to enclose the plurality of pixel openings 21. That is, a shape of the first isolation layer 41 may be the same as or similar to a shape of the pixel definition layer 20 in a direction parallel to the driver substrate 10, such that the first isolation layer 41 may form the mesh to enclose the plurality of pixel openings 21. In this way, a mask plate for patterning to form the pixel definition layer 20 may also be used in preparing the first isolation layer 41, i.e., the first isolation layer 41 and the pixel definition layer 20 may be formed based on the same mask plate, and the number of mask plates may not be increased.

Further, the first isolation layer 41 may repel the metal material, such that adjacent metal connection layers 333 may be isolated from each other, i.e., the metal connection layer 333 may be interrupted at a position where the first isolation layer 41 is arranged. In this way, transvers conductive crosstalk of the metal connection layers 333 may be effectively reduced. Therefore, when one of the plurality of sub-pixels 30 is lit, an upper one of the at least two light emitting function layers 32 of another sub-pixel 30 adjacent to the instant one sub-pixel 30 may not be lit, such that transvers crosstalk between the plurality of sub-pixels 30 may be prevented. Specifically, a material of the first isolation layer 41 may include a cathode patterning material (CPM), which may be incompatible with and repel from the metal material. The CPM may be a fluorine-containing organic material, such as a homosubstituted fluorine-substituted cyclic triphosphate compound. The CPM may be deposited on the pixel definition layer 20 by performing low-temperature vacuum evaporation, so as to form the first isolation layer 41. As the CPM is incompatible with the metal material, the metal material cannot be deposited on the first isolation layer 41. Therefore, when the metal connection layer 333 is subsequently made by performing evaporation on the metal material, the metal material cannot be deposited on the first isolation layer 41, such that the metal connection layer 333 may be interrupted at the position where the first isolation layer 41 is arranged, and that is, metal connection layers 333 of adjacent sub-pixels 30 may be disconnected from each other at a position where the pixel definition layer 20 is arranged.

Furthermore, in a subsequent process of performing evaporation to form the light emitting function layers 32, when the FMM frequently rubs the pixel definition layer 20 and the photo spacer 22 during alignment, exposure of the metal connection layer 333 due to rubbing may be reduced due to the metal connection layers 333 being disconnected from each other at the first isolation layer 41 on the pixel definition layer 20. In this way, a possibility of the distance between the metal connection layer 333 and the cathode electrode 34 being reduced may be reduced. Therefore, direct conduction between the metal connection layer 333 and the cathode electrode 34 caused by a large current breaking through the light emitting function layers 32, due to the metal connection layer 333 being excessively close to the cathode electrode 34, may be avoided, and the poor touch effect of the screen, caused by the metal connection layer 333 and the cathode electrode 34 being tandem conducted to each other, may be prevented.

As shown in FIGS. 1 to 3, FIG. 3 is another cross-sectional view of the display panel 100 according to the first embodiment of the present disclosure. Specifically, in a radial direction of each pixel opening 21, a width of the first isolation layer 41 may be less than or equal to a width of the side surface of the pixel definition layer 20 away from the driver substrate 10. It may be interpreted as an orthographic projection of the first isolation layer 41 on the pixel definition layer 20 being located within, or coinciding with, an upper surface of the pixel definition layer 20. The side surface of the pixel definition layer 20 away from the driver substrate 10 may be the upper surface of the pixel definition layer 20.

As shown in FIGS. 1 and 2, in the present embodiment, in the radial direction of the pixel opening 21, the width of the first isolation layer 41 may be less than the width of the side surface of the pixel definition layer 20 away from the driver substrate 10. That is, the orthographic projection of the first isolation layer 41 on the pixel definition layer 20 may be located within the upper surface of the pixel definition layer 20 and may not completely cover the pixel definition layer 20. In this way, the metal connection layer 333 in the charge generation layer 33 may be interrupted at the position of the first isolation layer 41 on the pixel definition layer 20, such that transverse conductive crosstalk may be reduced. Furthermore, in the subsequent process of performing evaporation to form the second charge generation layer 332 and the light emitting function layers 32, when the FMM frequently rubs the pixel definition layer 20 for aligning, exposure of the metal connection layer 333 due to the rubbing may be reduced, and possibility of the distance between the metal connection layer 333 and the cathode electrode 34 being reduced may be reduced. Therefore, direct conduction between the metal connection layer 333 and the cathode electrode 34 caused by a large current breaking through the light emitting function layers 32, due to the metal connection layer 333 being excessively close to the cathode electrode 34, may be avoided, and the poor touch effect of the screen, caused by the metal connection layer 333 and the cathode electrode 34 being tandem conducted to each other, may be prevented. Moreover, according to the above configuration, in the radial direction of the pixel opening 21, the width of the first isolation layer 41 may be less than the width of the pixel definition layer 20, such that the amount of materials used for the first isolation layer 41 may be reduced, and preparation costs may be lowered. Furthermore, since the shape of the first isolation layer 41 may be substantially the same as the shape of the pixel definition layer 20, the first isolation layer 41 and the pixel definition layer 20 may be prepared by sharing one mask plate, only processing parameters need to be adjusted, such as parameters related to evaporation, such as an evaporation angle and an evaporation rate, or etching process parameters, and so on. The parameters may be determined based on preparation processes and structural dimensions.

As shown in FIG. 3, in the present embodiment, in the radial direction of the pixel openings 21, the width of the first isolation layer 41 may be equal to the width of the side surface of the pixel definition layer 20 away from the driver substrate 10. That is, the orthographic projection of the first isolation layer 41 on the pixel definition layer 20 may coincide with the upper surface of the pixel definition layer 20. Alternatively, it may be interpreted as the first isolation layer 41 exactly covering the upper surface of the pixel definition layer 20. By arranging the first isolation layer 41 to cover the upper surface of the pixel definition layer 20, the metal connection layer 333 may be better confined within the pixel opening 21, the transverse conductive crosstalk may be reduced, and when performing evaporation for forming the second charge generation layer 332 and the light emitting function layers 32, possibility of the metal connection layer 333 being exposed caused by the FMM, during aligning, rubbing the pixel definition layer 20 may be further reduced, and tandem conduction between the metal connection layer 333 and the cathode electrode 34 may be reduced. Similarly, according to the above configuration, the width of the first isolation layer 41 may be the same as the width of the pixel definition layer 20 in the radial direction of the pixel opening 21, and the first isolation layer 41 and the pixel definition layer 20 may be prepared by sharing one mask plate.

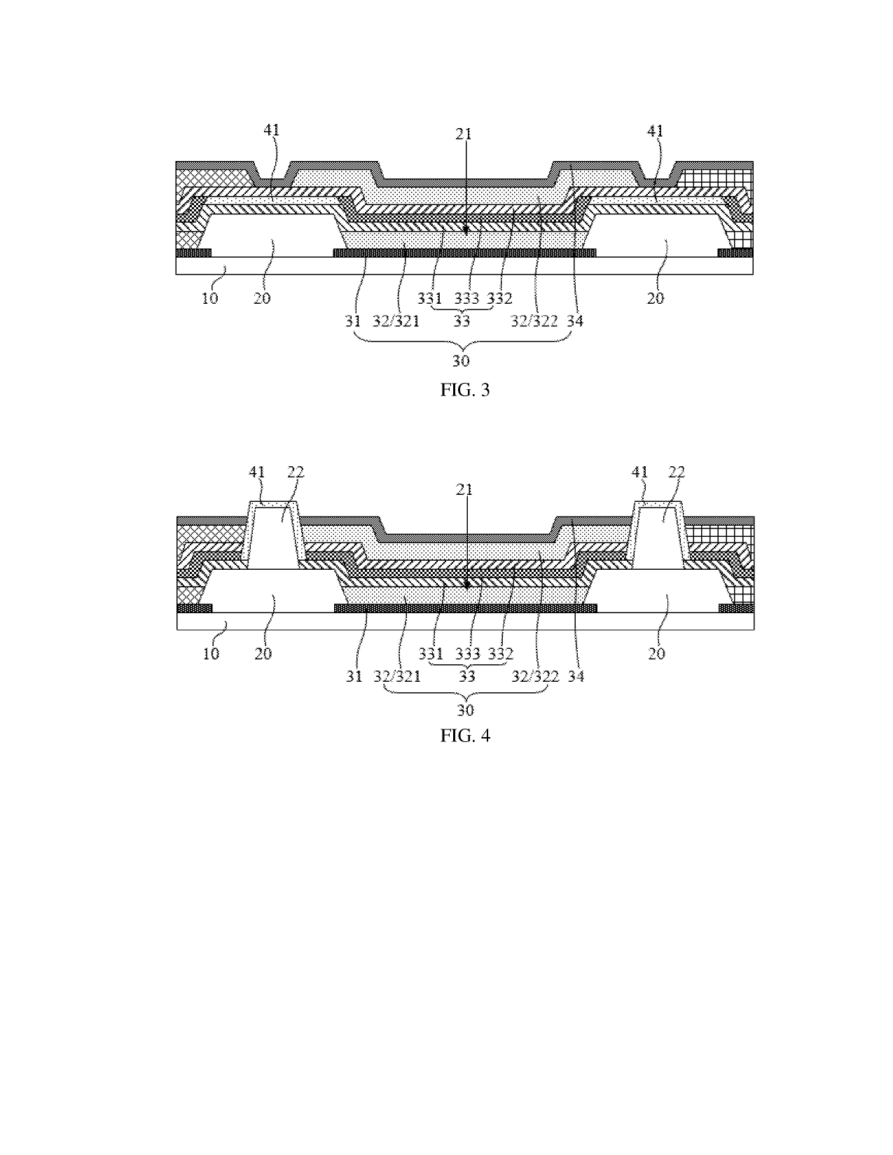

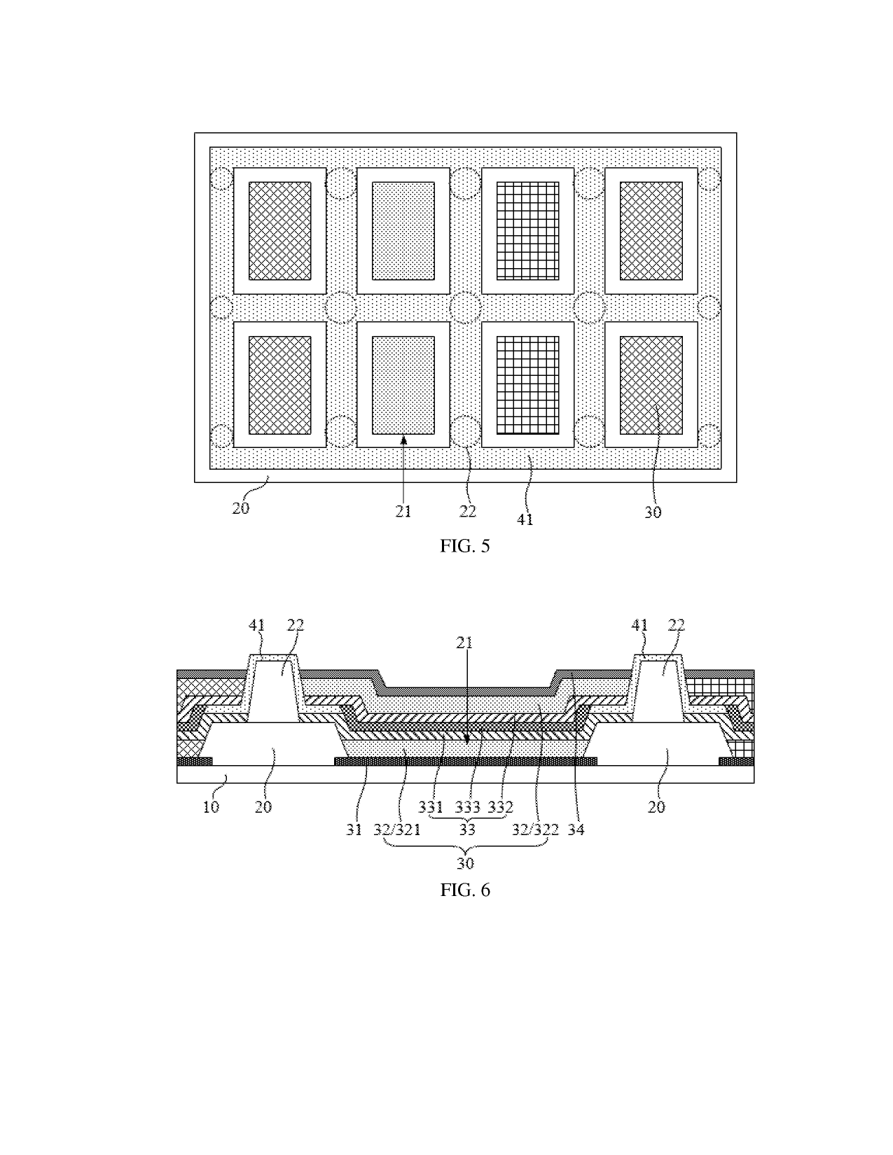

As shown in FIGS. 4 and 5, FIG. 4 is a cross-sectional view of the display panel according to a second embodiment of the present disclosure; and FIG. 5 is a plane view of the display panel 100 according to the second embodiment of the present disclosure. In the present embodiment, the display panel 100 may further include a plurality of photo spacers 22 that are spaced apart from each other and are protrudingly arranged on the pixel definition layer 20 to support the mask plate. The first isolation layer 41 may be arranged on a side surface of each of the plurality of photo spacers 22 away from the driver substrate 10.

The plurality of photo spacers 22 may be spaced apart from each other and may be arranged on the pixel definition layer 20 to support the mask plate to protect various film layers on the display panel 100. The plurality of photo spacers 22 may be prepared by a patterning process, such as photolithography, deposition, inkjet printing, and other patterning processes. A material of the photo spacer 22 may be prepared using a transparent insulating material, such as polystyrene (PS).

Specifically, the first isolation layer 41 may be arranged on the side surface of the photo spacer 22 away from the driver substrate 10. That is, the first isolation layer 41 may cover a surface of the photo spacer 22 protruding from the pixel definition layer 20. It may be interpreted as the first isolation layer 41 being deposited on the surface of the pixel definition layer 20 and the side surface of the photo spacer 22 away from the driver substrate 10 to form a continuous mesh film layer, such that the metal connection layer 333 between adjacent sub-pixels 30 may be confined within the respective pixel opening 21. In this way, the transverse conductive crosstalk caused by metal connection layers 333 may be reduced, tandem conduction between the metal connection layer 333 and the cathode connection layer may be reduced, and the poor touch effect of the screen may be prevented.

As shown in FIGS. 5 and 6, FIG. 6 is another cross-sectional view of the display panel according to the second embodiment of the present disclosure. Specifically, in the radial direction of the pixel opening 21, the width of the first isolation layer 41 may be greater than or equal to the width of the photo spacer 22 to cover at least the photo spacer 22 and a portion of the pixel definition layer 20.

Similarly to the first embodiment, in the radial direction of the pixel opening 21, the width of the first isolation layer 41 may be greater than or equal to the width of the photo spacer 22, such that the surface of the photo spacer 22 that is exposed out of the pixel definition layer 20 may be completely covered by the first isolation layer 41. To be noted that in a deposition process such as evaporation, the photo spacer 22 may substantially be configured to support the mask plate, therefore, during aligning the mask plate with the driver substrate 10, the mask plate may frequently rub the photo spacer 22, and the metal connection layer 333 may be easily exposed at a rubbing position, and therefore, the distance between the metal connection layer 333 at the rubbing position and the cathode electrode 34 may be excessively small, such that tandem conduction between the metal connection layer 333 and the cathode electrode 34 may be caused easily, and the poor touch effect of the screen may be caused. In the present embodiment, the first isolation layer 41 may cover the exposed surface of the photo spacer 22, and therefore, when the first isolation layer 41 is formed by evaporation subsequently, the first isolation layer 41 may not be deposited on the photo spacer 22. In this way, a risk of the first isolation layer 41 being exposed due to rubbing may be reduced, and the tandem conduction between the metal connection layer 333 and the cathode electrode 34 may be reduced, such that the poor touch effect of the screen may be reduced.

Furthermore, the first isolation layer 41 extends along the extension direction of the pixel definition layer 20 to form one continuous mesh film layer to cover at least a portion of the pixel definition layer 20 in the radial direction of the pixel opening 21. Since the metal connection layer 333 cannot be deposited on the first isolation layer 41, metal connection layers 333 may be disconnected from each other at the position where the pixel definition layer 20 is arranged, such that metal connection layers 333 in the adjacent sub-pixels 30 may be separated from each other. In this way, the metal connection layer 333 in one of the plurality of sub-pixels 30 may be independent from the metal connection layer 333 in another one of the plurality of sub-pixels 30. Therefore, pixel lighting crosstalk caused by transverse conductive crosstalk of the metal connection layers 333 may be reduced, the product yield may be improved.

As shown in FIG. 5, in the present embodiment, in the radial direction of the pixel opening 21, the width of the first isolation layer 41 may be equal to the width of the photo spacer 22, the first isolation layer 41 may cover the photo spacer 22 and at least a portion of the pixel definition layer 20. In this way, the risk of the metal connection layer 333 being exposed, due to the mask plate rubbing the photo spacer 22, may be reduced; and tandem conduction between the metal connection layer 333 and the cathode electrode may be reduced. Furthermore, the metal connection layer 333 of each sub-pixel 30 may be independent, pixel lighting crosstalk caused by transverse conductive crosstalk of the metal connection layers 333 may be reduced, such that the product yield may be improved, transverse conductive crosstalk during pixel lighting may be reduced, and the product yield may be improved. The amount of materials used for the first isolation layer 41 may be reduced, and production costs may be reduced.

As shown in FIG. 6, in the present embodiment, in the radial direction of the pixel opening 21, the width of the first isolation layer 41 may be greater than the width of the photo spacer 22 and may be the same as the width of the pixel definition layer 20. In this way, the first isolation layer 41 may cover both the photo spacer 22 and the pixel definition layer 20, facilitating the metal connection layer 333 to be confined inside the pixel opening 21, further reducing the risk of the metal connection layer 333 being exposed due to the mask plate 22 rubbing the photo spacer 22. Tandem conduction between the metal connection layer 333 and the cathode electrode may be reduced. The metal connection layers 333 of the plurality of sub-pixels 30 may be better separated from each other, further reducing pixel lighting crosstalk caused by transverse conductive crosstalk of the metal connection layers 333.

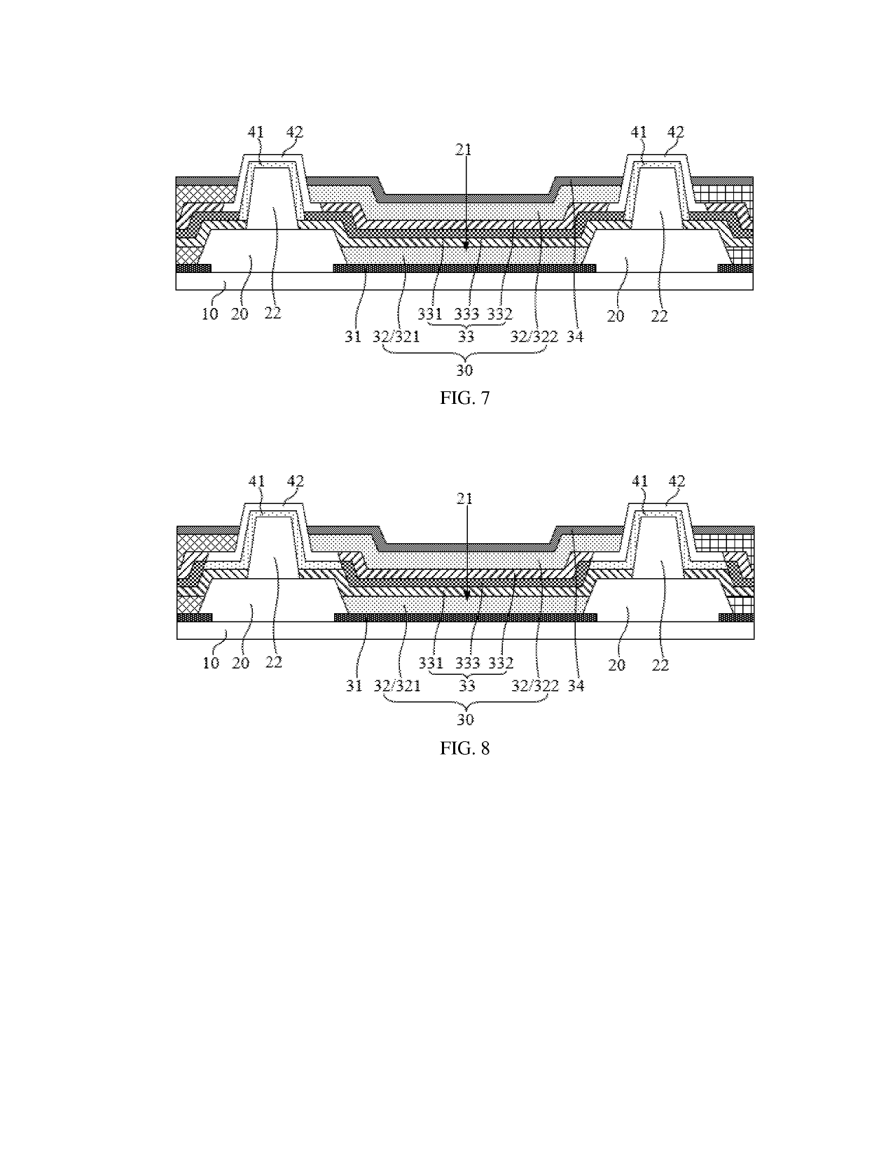

As shown in FIG. 7, FIG. 7 is a vertical cross-sectional view of the display panel 100 according to a third embodiment of the present disclosure. In the present embodiment, a second isolation layer 42 may cover a side surface of the first isolation layer 41 away from the driver substrate 10, a material of the second isolation layer 42 may be an insulating material.

Specifically, when it is difficult for the first isolation layer 41 to completely prevent deposition of the metal material, in order to further isolate the metal connection layer 333 from the cathode electrode 34 and to reduce the transverse conductive crosstalk, after preparation of the metal connection layer 333 is completed, an insulating material may be arranged to cover the first isolation layer 41 to form the second isolation layer. By arranging the second isolation layer, the pixel definition layer 20 may further be separated from the metal connection layer 333 at the photo spacer and the cathode electrode 34. In this way, stability of insulation between the metal connection layer 333 and the cathode electrode 34 may be improved, further reducing the tandem conduction between the metal connection layer 333 and the cathode electrode 34. The material of the second isolation layer may be an insulating inorganic or organic insulating material having better insulating performance, such as lithium fluoride (LiF), an oxide insulating material, or a CPL material, and so n, which may be determined according to the actual needs.

As shown in FIGS. 7 and 8, FIG. 8 is another vertical cross-sectional view of the display panel 100 according to the third embodiment of the present disclosure. Specifically, an orthographic projection of the second isolation layer 42 on the pixel definition layer 20 may cover an orthographic projection of the first isolation layer 41 on the pixel definition layer 20. Alternatively, the orthographic projection of the second isolation layer 42 on the pixel definition layer 20 may coincide with the orthographic projection of the first isolation layer 41 on the pixel definition layer 20. That is, in the radial direction of the pixel opening 21, an edge of the second isolation layer 42 at least coincides with an edge of the first isolation layer 41, enabling the second isolation layer 42 to completely cover the first isolation layer 41, such that insulating performance of the second isolation layer 42 for insulating the metal connection layer 333 from the cathode electrode 34 may be improved, and the risk of tandem conduction between the metal connection layer 333 and the cathode electrode 34 may be reduced.

As shown in FIG. 7, in the present embodiment, in the radial direction of the pixel opening 21, the width of the first isolation layer 41 may be smaller than the width of the pixel definition layer 20, and the orthographic projection of the first isolation layer 41 on the pixel definition layer 20 may be located inside the upper surface of the first pixel isolation layer. The orthographic projection of the second isolation layer 42 on the pixel definition layer 20 may cover the orthographic projection of the first isolation layer 41 on the pixel definition layer 20. That is, along the radial direction of the pixel opening 21, edges of two sides of the second isolation layer 42 may extend out of the first isolation layer 41 to completely cover the first isolation layer 41. In this way, the metal connection layer 333 and the cathode electrode 34 are further isolated from each other, tandem conduction between the metal connection layer 333 and the cathode electrode 34 may be prevented, and transverse conductive crosstalk of the metal connection layers 333 may be reduced.

As shown in FIG. 8, in the present embodiment, in the radial direction of the pixel opening 21, the width of the first isolation layer 41 may be the same as the width of the second isolation layer 42, and the orthographic projection of the second isolation layer 42 on the pixel definition layer 20 may coincide with the orthographic projection of the first isolation layer 41 on the pixel definition layer 20. In this way, the second isolation layer 42 and the first isolation layer 41 may have a same shape and a same size. The second isolation layer 42 may exactly and completely cover the first isolation layer 41. Therefore, the metal connection layer 333 and the cathode electrode 34 may further be isolated from each other, tandem conduction between the metal connection layer 333 and the cathode electrode 34 may be prevented, and transverse conductive crosstalk of the metal connection layers 333 may be reduced.

Specifically, a method of manufacturing the display panel 100 provided in the above embodiments will be described in detail in the following embodiments.

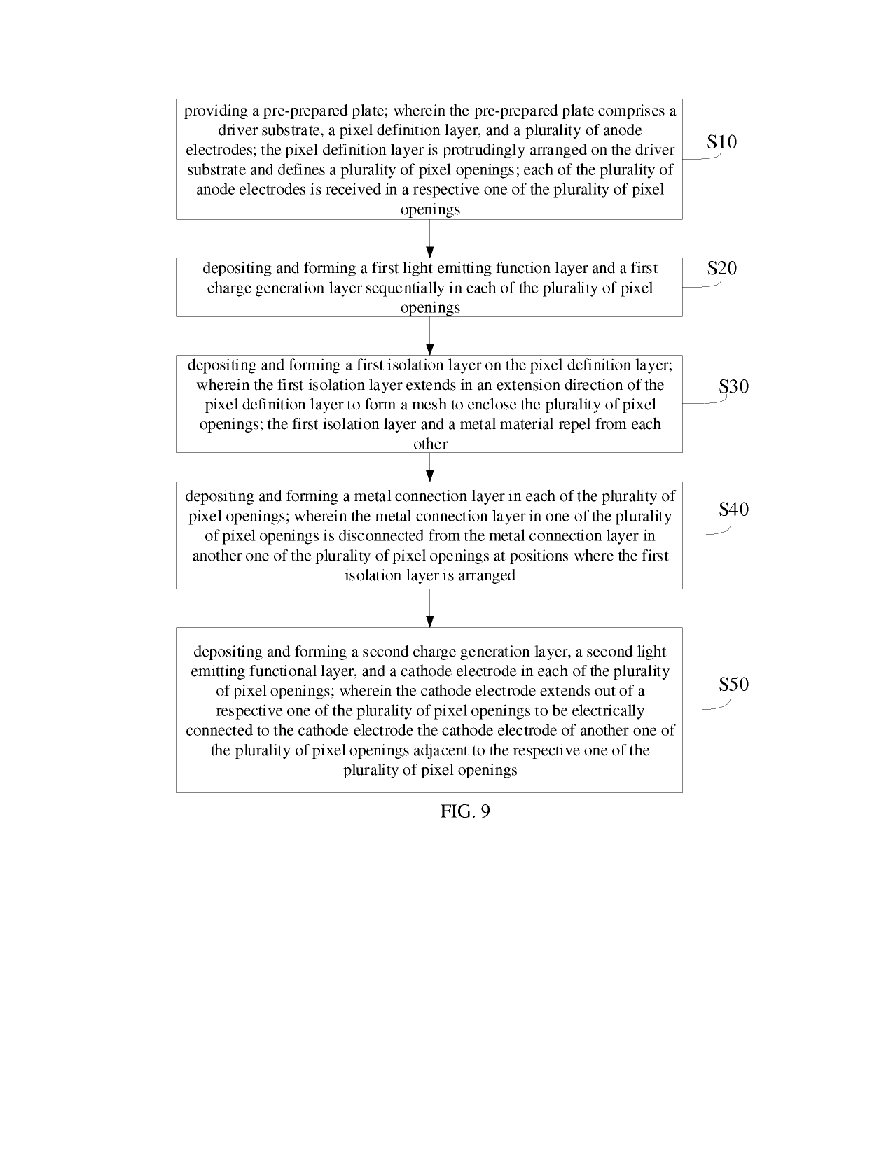

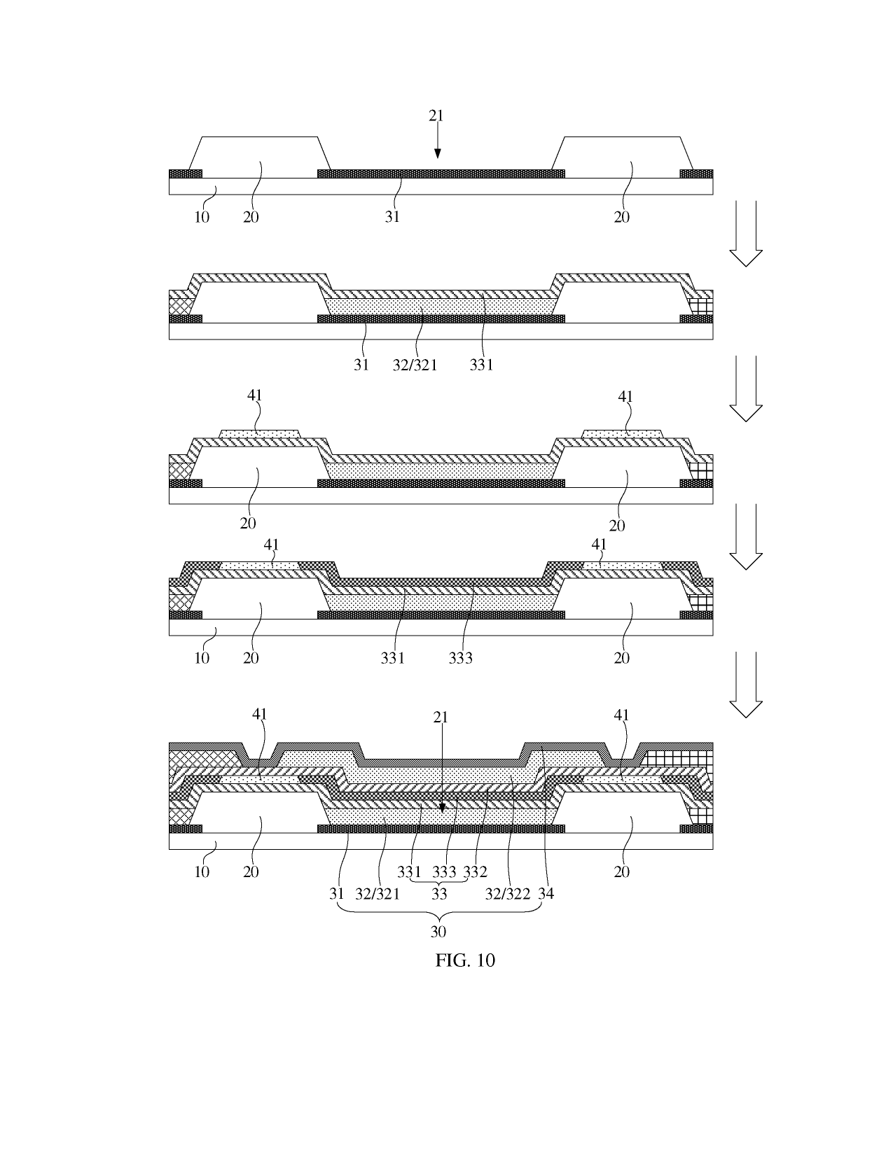

As shown in FIGS. 9 and 10, FIG. 9 is a flow chart of a method of manufacturing the display panel 100 according to a first implementation of the present disclosure; and FIG. 10 is a structural schematic view of a component corresponding to the method shown in FIG. 9. In the present embodiment, the method of manufacturing the display panel 100 is provided, the method may be performed to manufacture the display panel 100 provided in the above embodiments, the method may include the following operations.

In an operation S10, a pre-prepared plate may be provided. The pre-prepared plate may include the driver substrate 10, the pixel definition layer 20, and the plurality of anode electrodes 31. The pixel definition layer 20 may protrude out from the driver substrate 10, the plurality of pixel openings 21 may be defined in the pixel definition layer 20. Each of the plurality of anode electrodes 31 may be received in the respective one of the plurality of pixel openings 21.

In an operation S20, the first light emitting function layer 321 and the first charge generation layer 331 may be sequentially deposited in each pixel opening 21.

In an operation S30, the first isolation layer 41 may be deposited and form on the pixel definition layer 20. The first isolation layer 41 may extend along the extension direction of the pixel definition layer 20 to form the mesh to enclose each pixel opening 21. The first isolation layer 41 and the metal material may repel from each other.

In an operation S40, the metal connection layer 333 may be deposited and formed in each pixel opening 21, and the metal connection layer 333 in one pixel opening 21 may be disconnected from the metal connection layer 333 in another one pixel opening 21 at a position where the first isolation layer 41 is arranged.

In an operation S50, the second charge generation layer 332, the second light emitting function layer 322, and the cathode electrode 34 may be sequentially deposited in each pixel opening 21. The cathode electrode 34 may extend out of one pixel opening 21 and may be electrically connected with the cathode electrode 34 in another pixel opening 21 adjacent to the one pixel opening 21.

The pre-prepared plate including the driver substrate 10, the pixel definition layer 20 and the anode electrode 31, may be interpreted as the pre-prepared plate being a substrate that the anode electrode 31 and the pixel definition layer 20 are well prepared on the driver substrate 10. Specifically, the operation of providing the pre-prepared plate may include following operations.

In an operation S11, providing the driver substrate 10.

In an operation S12, the plurality of anode electrodes 31 may be prepared on the driver substrate 10.

In an operation S13, the pixel definition layer 20 may be prepared on the driver substrate 10.

The plurality of anode electrodes 31 may be prepared by performing an evaporation process or a photolithography process to achieve patterning. The plurality of anode electrodes 31 may be respectively electrically connected to the plurality of sub-pixel drive circuits on the driver substrate 10 to serves as anodes of the plurality of sub-pixels to receive the drive signals. The plurality of anode electrodes 31 may be arranged in the array, and the plurality of anode electrodes may be formed by patterning based on arrangement of the plurality of sub-pixels 30. The structure, the material, and the function of the plurality of anode electrodes 31 may be the same as and referred to those described in the above embodiments.

The pixel definition layer 20 may be prepared by photolithography or other patterning processes to form the plurality of pixel openings 21 corresponding to the plurality of anode electrodes 31. The plurality of pixel openings 21 may be in one-to-one correspondence with the plurality of anode electrodes 31. In this way, each of the plurality of anode electrodes 31 may be exposed from the respective one of the plurality of pixel openings 21 to be in contact with and connected with the light emitting functional layer 32 that is formed subsequently.

Specifically, the operation S20 may specifically include following operations.

In an operation S21, the first hole transport layer, the first light emitting layer, and the first electron transport layer may be sequentially deposited in each pixel opening 21 to form the first light emitting function layer 321 on the anode electrode 31.

In an operation S22, the first charge generation layer 331 may be deposited on the first light emitting function layer 321.

The structure and the function of the first light emitting function layer 321 may be the same as and referred to those in the above embodiments, which will not be repeated herein. The first charge generation layer 331 may be the N-type charge generation layer 33 and may specifically be deposited on the first light emitting function layer 321 by the evaporation process and may be configured to generate electrons and transmit the electrons to the electron transport layer.

In the operation S30, the first isolation layer 41 may be formed by depositing on the pixel definition layer 20, using the high-precision fine metal mask (FMM), enabling the first isolation layer 41 to form the continuous mesh film layer on the pixel definition layer 20 to enclose each pixel opening 21. Specifically, the insulating material that is incompatible with the metal material may be used for performing the evaporation to form the first isolation layer 41. In this way, when subsequently performing the evaporation on the metal material, the metal material cannot be adhered to the first isolation layer 41. Specifically, the cathode patterning material (CPM) may be used for the evaporation to form the first isolation layer 41, and the CPM material may be the fluorine-containing organic material, such as the homo-substituted fluorine-substituted cyclic trisphosphorine compound, which is incompatible with the metal material. Specifically, the CPM material may be deposited on the pixel definition layer 20 by performing low-temperature vacuum evaporation to form the first isolation layer 41.

In the operation S40, a common metal mask (CMM) may be used to deposit the metal connection layer 333 on the first light emitting functional layer 321. Since the first isolation layer 41 may be formed on the pixel definition layer 20, when performing the evaporation to form the metal connection layer 333, the metal material cannot be attached to the first isolation layer 41. In this way, the metal connection layer 333 in one pixel opening may be disconnected from the metal connection layer 333 in another pixel opening at the position where the first isolation layer 41 is arranged. In this way, the risk of crosstalk of pixel lighting caused by transverse conductive crosstalk of metal connection layers 333 may be reduced.

Specifically, the operation S50 may include following operations.

In an operation S51, the second charge generation layer 332 may be deposited on the metal connection layer 333.

In an operation S52, the second hole transport layer, the second light emitting layer, and the second electron transport layer may be sequentially deposited on the second charge generation layer 332 in each pixel opening 21, so as to form the second light emitting function layer 322 on the charge generation layer 33.

In an operation S53, the cathode electrode 34 may be deposited on the second light emitting function layer 322.

In the operations S51, S52, and S53, the mask plate may be used, and in each of the operations S51, S52, and S53, the mask plate may be aligned to the pre-prepared plate firstly, and subsequently, evaporation and deposition may be performed. In a process of aligning the mask plate, the mask plate may be inevitably rub the pixel definition layer 20. Frequent rubbing may lead the metal connection layer 333 at rubbing positions to be exposed. In the present embodiment, the first isolation layer 41 may be formed on the pixel definition layer 20 firstly, such that the metal connection layer 333 may be unable to be deposited on the first isolation layer 41. Therefore, in the subsequent operations S51, S52, and S53, the risk of the metal connection layer 333 being exposed due to rubbing caused by alignment of the mask plate may be effectively reduced, the risk of tandem conduction between the metal connection layer 333 and the cathode electrode 34 at the pixel definition layer 20 may be reduced, and the product yield may be improved.

Specifically, in the operations of preparing the first charge generation layer 331, the metal connection layer 333, the second charge generation layer 332, and the cathode electrode 34, the common metal mask (CMM) may be used for deposition and evaporation, i.e., the common metal mask version (CMM) may be shared, such that manufacturing costs may be reduced.

Specifically, in the radial direction of each pixel opening 21, the width of the first isolation layer 41 may be less than or equal to the width of the side surface of the pixel definition layer 20 away from the driver substrate 10, which is the same as and referred to the configuration described in the above embodiments and will not be repeated herein.

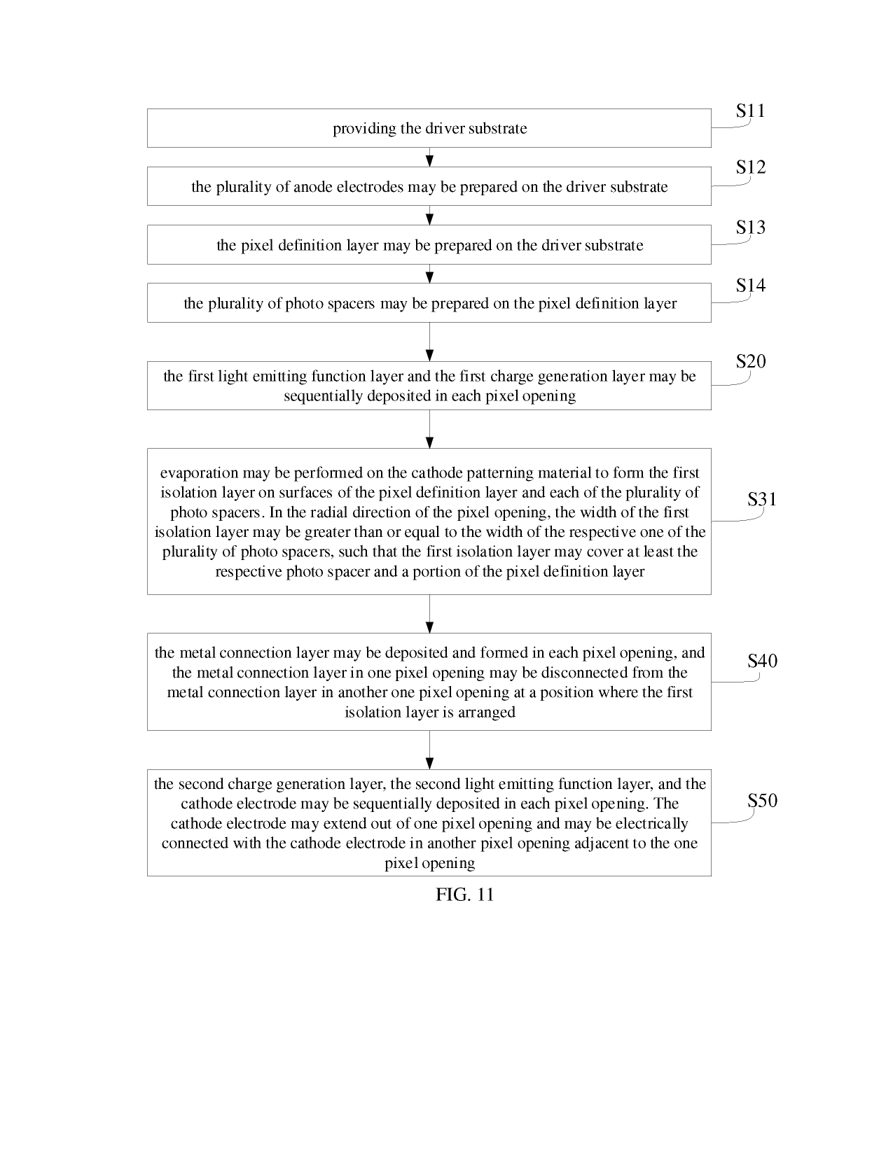

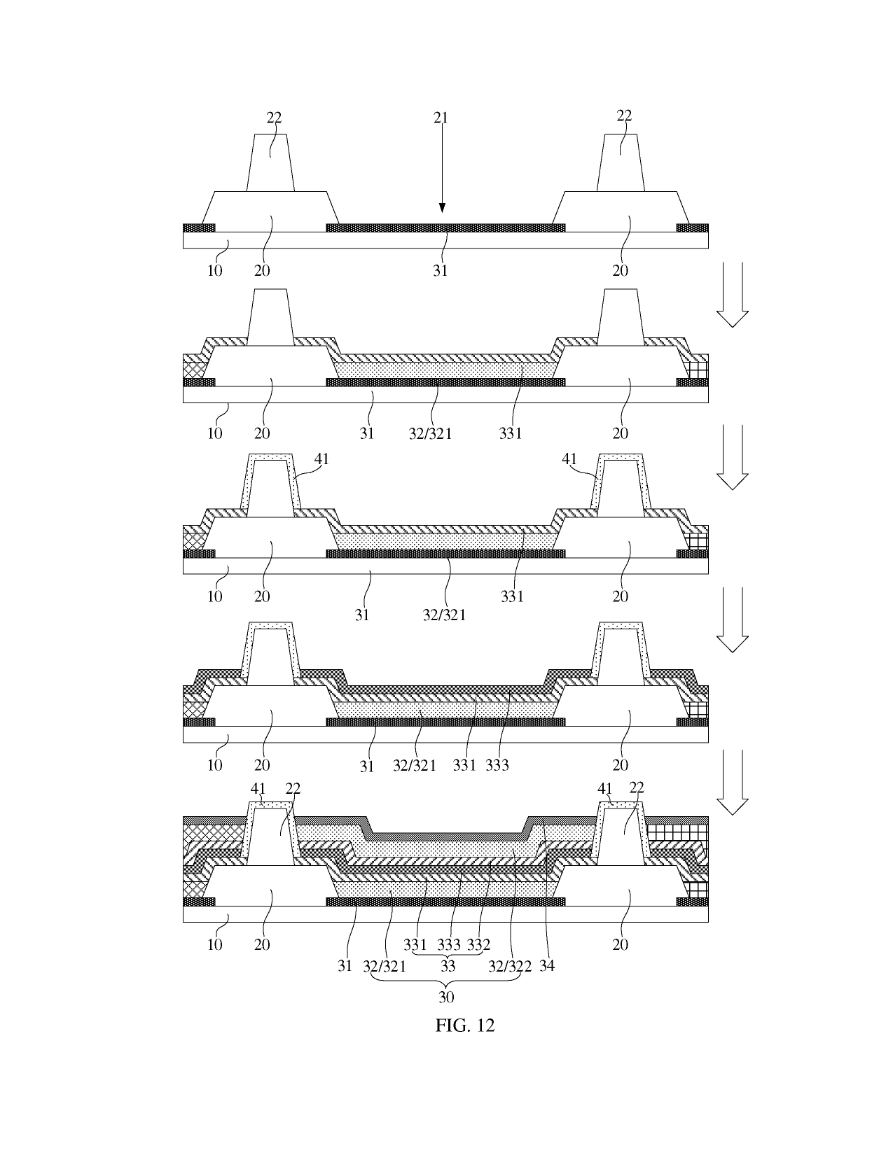

As shown in FIGS. 11 and 12, FIG. 11 is a flow chart of a method of manufacturing the display panel 100 according to a second implementation of the present disclosure; and FIG. 12 is a structural schematic view of a component corresponding to the method shown in FIG. 11. In the present embodiment, the pre-prepared plate further includes a plurality of photo spacers 22 that are spaced apart from each other and are protrudingly disposed on the pixel definition layer 20 to support the mask plate.

The operation S30 of depositing and forming the first isolation layer 41 on the pixel definition layer 20 may include following operations.

In an operation S31, evaporation may be performed on the cathode patterning material to form the first isolation layer 41 on surfaces of the pixel definition layer 20 and each of the plurality of photo spacers 22. In the radial direction of the pixel opening 21, the width of the first isolation layer 41 may be greater than or equal to the width of the respective one of the plurality of photo spacers 22, such that the first isolation layer 41 may cover at least the respective photo spacer 22 and a portion of the pixel definition layer 20.

Specifically, the operation S10 of providing the pre-prepared plate may further include following operations.

In an operation S14, the plurality of photo spacers 22 may be prepared on the pixel definition layer 20.

Forming the plurality of photo spacers 22 on the pixel definition layer 20 may specifically be achieved by performing a photolithography process or other patterning processes. The plurality of photo spacers 22 may substantially configured to support the mask plate to protect each film layer on the display panel 100. The material of the plurality of photo spacers 22 may be prepared using the transparent insulating material, such as polystyrene (PS) and the like. Specifically, since the mask plate is supported by the plurality of photo spacers 22, rubbing between the mask plate and the pixel definition layer 20 may be reduced. Therefore, the problem of the metal connection layer 333 being exposed from the pixel definition layer 20 due to the rubbing may be reduced; the risk of tandem conduction between the metal connection layer 333 and the cathode electrode 34 at positions where the pixel definition layer 20 and the plurality of photo spacers 22 are arranged may be reduced; and the product yield may be improved.

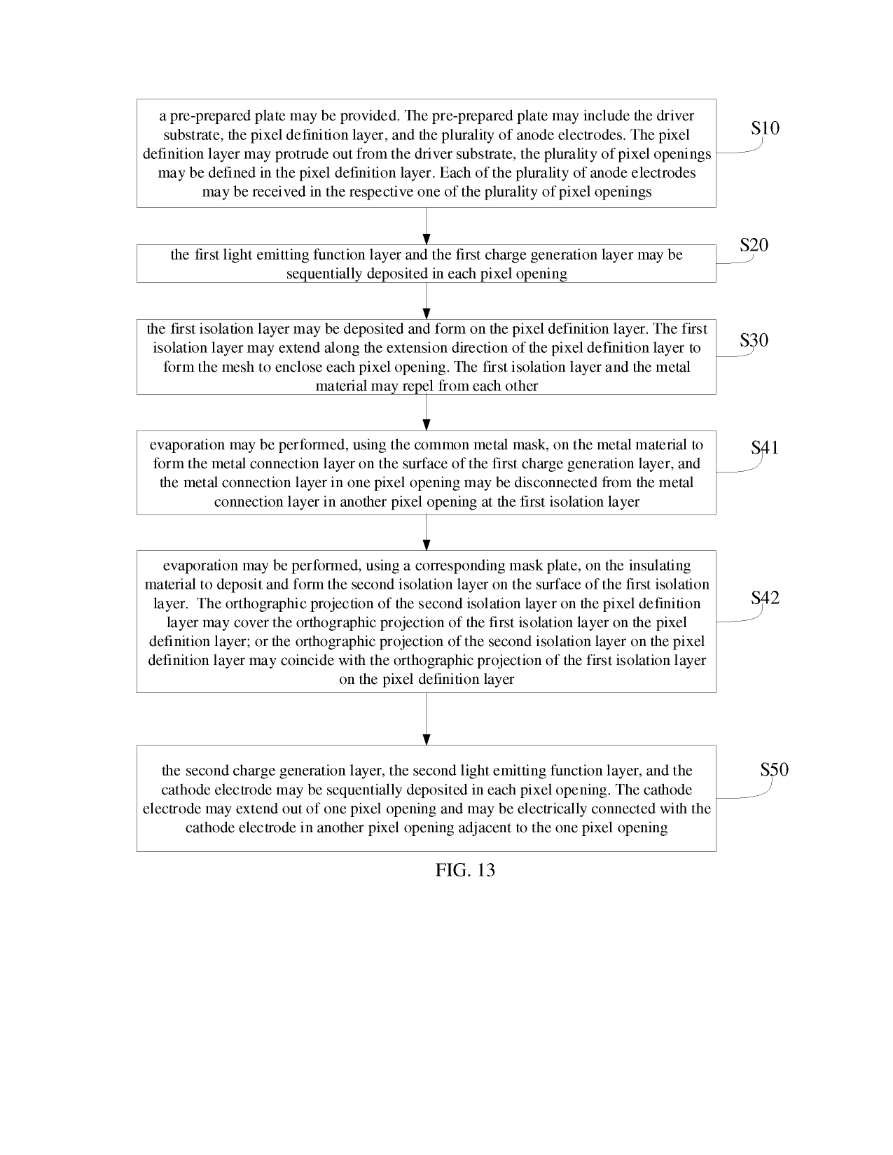

As shown in FIGS. 13 and 14, FIG. 13 is a flow chart of a method of manufacturing the display panel 100 according to a third implementation of the present disclosure; and FIG. 14 is a structural schematic view of a component corresponding to the method shown in FIG. 13. In the present embodiment, the operation S40 of depositing and forming the metal connection layer 333 in each pixel opening 21 and the metal connection layer 333 in one pixel opening 21 being disconnected from the metal connection layer 333 in another pixel opening 21 at the first isolation layer 41 may include following operations.

In an operation S41, evaporation may be performed, using the common metal mask, on the metal material to form the metal connection layer 333 on the surface of the first charge generation layer 331, and the metal connection layer 333 in one pixel opening 21 may be disconnected from the metal connection layer 333 in another pixel opening 21 at the first isolation layer 41.

After the operation S41, the method may further include the following.

In an operation S42, evaporation may be performed, using a corresponding mask plate, on the insulating material to deposit and form the second isolation layer 42 on the surface of the first isolation layer 41. The orthographic projection of the second isolation layer 42 on the pixel definition layer 20 may cover the orthographic projection of the first isolation layer 41 on the pixel definition layer 20; or the orthographic projection of the second isolation layer 42 on the pixel definition layer 20 may coincide with the orthographic projection of the first isolation layer 41 on the pixel definition layer 20.

The operation S41 may be the same as the above embodiment, the CMM may be used to perform the evaporation on the metal material to deposit and form the metal connection layer 333 on the first light emitting function layer 321. The metal material may be metal conductive materials, such as (Au), silver (Ag), copper (Cu), aluminum (Al), or an alloy material of more than one of the above metal materials. The structure and function of the metal connection layer 333 may be the same as or similar to and may be referred to those described in the above embodiments.

In the operation S42, the mask plate used for preparing the first isolation layer 41 may be used to perform the evaporation on the insulating material, so as to deposit and form the second isolation layer 42 on the surface of the first isolation layer 41. When the first isolation layer 41 may not completely inhibit attachment of the metal material, in order to further isolate the metal connection layer 333 from the cathode electrode 34 and to reduce the transverse conductive crosstalk, after preparation of the metal connection layer 333 is completed, the insulating material may be arranged to cover the first isolation layer 41 to form the second isolation layer. The second isolation layer may further isolate the metal connection layer 333 from the cathode electrode 34 at the pixel definition layer 20 and the photo spacer. In this way, stability of insulation between the metal connection layer 333 and the cathode electrode 34 may be improved, and the problem of tandem conduction between the metal connection layer 333 and the cathode electrode 34 may further be reduced.

Specifically, the orthographic projection of the second isolation layer 42 on the pixel definition layer 20 may cover the orthographic projection of the first isolation layer 41 on the pixel definition layer 20; or, the orthographic projection of the second isolation layer 42 on the pixel definition layer 20 may coincide with the orthographic projection of the first isolation layer 41 on the pixel definition layer 20. The instant configuration may be the same as the configuration of the second isolation layer 42 and the first isolation layer 41 as described in the above embodiments, same technical effects can be achieved, details of the instant configuration may be referred to the above embodiments and will not be repeated herein.

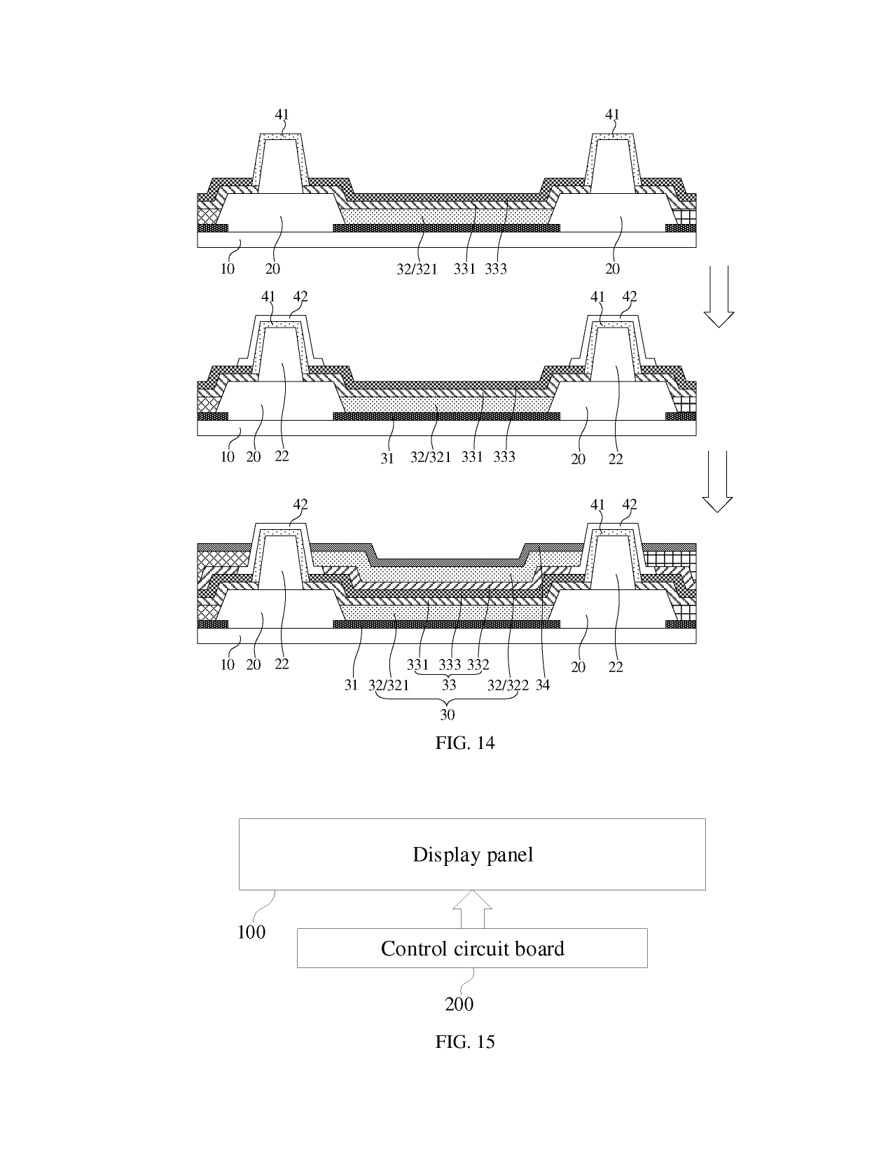

As shown in FIG. 15, FIG. 15 is a structural schematic view of a display apparatus corresponding to an embodiment of the present disclosure. In the present embodiment, the display apparatus is provided and may be configured in a displaying technical field, such as in a tablet computer, in a mobile phone, in a vehicle, in VR glasses, in a lighting device, and the like.

The display apparatus may include the following.

The display panel 100 as provided in the above embodiments may be arranged.

A control circuit board 200 may be electrically connected to the display panel 100 and configured to control the display panel 100 to display a corresponding image.

The structure and function of the display panel 100 may be the same as or similar to the specific structure and function of the display panel 100 as provided in the above embodiments. Same technical effects can be achieved, details thereof may be referred to the above relevant embodiments. Specifically, the display panel 100 may be prepared by the method provided in the above embodiments, and the method may be referred to relevant description in the above.

The control circuit board 200 may be electrically connected to the display panel and configured to provide the display panel 100 with various drive signals, power signals, and other drive signals required by the display panel 100, so as to control the display panel 100 to display the corresponding image.

In the present embodiment, the display apparatus may be a stacking tandem type OLED display apparatus, having high display brightness and a long service life. Moreover, by arranging the above-described display panel 100 in the display apparatus, a poor touch effect of the screen, caused by tandem conduction between the metal connection layer 333 of the charge generation layer 33 and the cathode electrode 34, may be prevented, and pixel lighting crosstalk caused by transverse conductive crosstalk of the metal connection layers 333 may be reduced, the product yield may be improved.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising:
a driver substrate;
a pixel definition layer, protrudingly arranged on the driver substrate and defining a plurality of pixel openings;
a plurality of sub-pixel, each of the plurality of sub-pixel comprising an anode electrode, at least two stacked light emitting function layers, and a cathode electrode, wherein the anode electrode, the at least two stacked light emitting function layers, and the cathode electrode are stacked in a respective one of the plurality of pixel openings; a charge generation layer is disposed between adjacent two of the at least two light emitting function layers; the charge generation layer comprises a first charge generation layer, a metal connection layer, and a second charge generation layer that are sequentially stacked; the cathode electrode extends out of one respective pixel opening and is electrically connected to the cathode electrode of another pixel opening adjacent to the one respective pixel opening;
wherein, a first isolation layer is arranged on a side surface of the pixel definition layer away from the driver substrate; the first isolation layer extends along an extension direction of the pixel definition layer to form a mesh to enclose the plurality of pixel openings; the first isolation layer and a metal material repel from each other, so as to isolate the metal connection layer of one respective pixel opening from the metal connection layer of another pixel opening adjacent to the one respective pixel opening.

2. The display panel according to claim 1, wherein the display panel further comprises a plurality of photo spacers that are spaced apart from each other and are protrudingly arranged on the pixel definition layer to support a mask plate; and the first isolation layer is further arranged on a side surface of each of the plurality of photo spacers away from the driver substrate.

3. The display panel according to claim 2, wherein in a radial direction of each of the plurality of pixel openings, a width of the first isolation layer is greater than or equal to a width of each of the plurality of photo spacers to at least cover each of the plurality of photo spacers and a portion of the pixel definition layer.

4. The display panel according to claim 2, wherein a second isolation layer is arranged on and covers a side surface of the first isolation layer away from the driver substrate; a material of the second isolation layer is an insulating material.

5. The display panel according to claim 4, wherein, an orthographic projection of the second isolation layer on the pixel definition layer covers an orthographic projection of the first isolation layer on the pixel definition layer.

6. The display panel according to claim 4, wherein, an orthographic projection of the second isolation layer on the pixel definition layer coincides with an orthographic projection of the first isolation layer on the pixel definition layer.

7. The display panel according to claim 4, wherein, in a radial direction of each of the plurality of pixel openings, an edge of the second isolation layer coincides with at least an edge of the first isolation layer.

8. The display panel according to claim 1, wherein, a material of the first isolation layer is a cathode patterning material that mutually repels with a metal material.

9. A method of manufacturing a display panel, comprising:
providing a pre-prepared plate; wherein the pre-prepared plate comprises a driver substrate, a pixel definition layer, and a plurality of anode electrodes; the pixel definition layer is protrudingly arranged on the driver substrate and defines a plurality of pixel openings; each of the plurality of anode electrodes is received in a respective one of the plurality of pixel openings;
depositing and forming a first light emitting function layer and a first charge generation layer sequentially in each of the plurality of pixel openings;
depositing and forming a first isolation layer on the pixel definition layer; wherein the first isolation layer extends in an extension direction of the pixel definition layer to form a mesh to enclose the plurality of pixel openings; the first isolation layer and a metal material repel from each other;
depositing and forming a metal connection layer in each of the plurality of pixel openings; wherein the metal connection layer in one of the plurality of pixel openings is disconnected from the metal connection layer in another one of the plurality of pixel openings at positions where the first isolation layer is arranged;
depositing and forming a second charge generation layer, a second light emitting functional layer, and a cathode electrode in each of the plurality of pixel openings; wherein the cathode electrode extends out of a respective one of the plurality of pixel openings to be electrically connected to the cathode electrode the cathode electrode of another one of the plurality of pixel openings adjacent to the respective one of the plurality of pixel openings.

10. The method according to claim 9, wherein, the pre-prepared plate further comprises a plurality of photo spacers that are spaced apart from each other and are protrudingly arranged on the pixel definition layer to support a mask plate; and
the depositing and forming a first isolation layer on the pixel definition layer, comprises:
performing evaporation, using a corresponding mask plate, on a cathode patterning material to deposit and form the first isolation layer on surfaces of the pixel definition layer and the plurality of photo spacers; wherein in a radial direction of each of the plurality of pixel openings, a width of the first isolation layer is greater than or equal to a width of each of the plurality of photo spacers to at least cover each of the plurality of photo spacers and a portion of the pixel definition layer.

11. The method according to claim 9, wherein, the depositing and forming a metal connection layer in each of the plurality of pixel openings, the metal connection layer in one of the plurality of pixel openings being disconnected from the metal connection layer in another one of the plurality of pixel openings at positions where the first isolation layer is arranged, comprises:
performing evaporation, using a common metal mask, on a metal material to deposit and form the metal connection layer on a surface of the first charge generation layer, wherein the metal connection layer in one of the plurality of pixel openings is disconnected from the metal connection layer in another one of the plurality of pixel openings at positions where the first isolation layer is arranged;
the method further comprises:
performing evaporation, using a corresponding mask plate, on an insulating material to deposit and form a second isolation layer on the surface of the first isolation layer; wherein, an orthographic projection of the second isolation layer on the pixel definition layer covers an orthographic projection of the first isolation layer on the pixel definition layer; or an orthographic projection of the second isolation layer on the pixel definition layer coincides with an orthographic projection of the first isolation layer on the pixel definition layer.

12. A display apparatus, comprising:
a display panel;
a control circuit board, electrically connected to the display panel and configured to control the display panel to display a corresponding image;
wherein, the display panel, comprises:
a driver substrate;
a pixel definition layer, protrudingly arranged on the driver substrate and defining a plurality of pixel openings;
a plurality of sub-pixel, each of the plurality of sub-pixel comprising an anode electrode, at least two stacked light emitting function layers, and a cathode electrode, wherein the anode electrode, the at least two stacked light emitting function layers, and the cathode electrode are stacked in a respective one of the plurality of pixel openings; a charge generation layer is disposed between adjacent two of the at least two light emitting function layers; the charge generation layer comprises a first charge generation layer, a metal connection layer, and a second charge generation layer that are sequentially stacked; the cathode electrode extends out of one respective pixel opening and is electrically connected to the cathode electrode of another pixel opening adjacent to the one respective pixel opening;
wherein, a first isolation layer is arranged on a side surface of the pixel definition layer away from the driver substrate; the first isolation layer extends along an extension direction of the pixel definition layer to form a mesh to enclose the plurality of pixel openings; the first isolation layer and a metal material repel from each other, so as to isolate the metal connection layer of one respective pixel opening from the metal connection layer of another pixel opening adjacent to the one respective pixel opening.

13. The display apparatus according to claim 12, wherein the display panel further comprises a plurality of photo spacers that are spaced apart from each other and are protrudingly arranged on the pixel definition layer to support a mask plate; and the first isolation layer is further arranged on a side surface of each of the plurality of photo spacers away from the driver substrate

14. The display apparatus according to claim 13, wherein in a radial direction of each of the plurality of pixel openings, a width of the first isolation layer is greater than or equal to a width of each of the plurality of photo spacers to at least cover each of the plurality of photo spacers and a portion of the pixel definition layer.

15. The display apparatus according to claim 13, wherein a second isolation layer is arranged on and covers a side surface of the first isolation layer away from the driver substrate; a material of the second isolation layer is an insulating material.

16. The display apparatus according to claim 15, wherein, an orthographic projection of the second isolation layer on the pixel definition layer covers an orthographic projection of the first isolation layer on the pixel definition layer.

17. The display apparatus according to claim 15, wherein, an orthographic projection of the second isolation layer on the pixel definition layer coincides with an orthographic projection of the first isolation layer on the pixel definition layer.

18. The display panel according to claim 15, wherein, in a radial direction of each of the plurality of pixel openings, an edge of the second isolation layer coincides with at least an edge of the first isolation layer.

19. The display apparatus according to claim 12, wherein, a material of the first isolation layer is a cathode patterning material that mutually repels with a metal material.
